(19) United States
(12) Patent Application Publication
(10) Pub. No.: US 2024/0213368 A1
(43) Pub. Date: Jun. 27, 2024

(54) SEMICONDUCTOR DEVICE AND THE MANUFACTURING METHOD THEREOF

(71) Applicant: HON HAI PRECISION INDUSTRY CO., LTD., New Taipei City (TW)

(72) Inventor: Yun-Hung SHEN, Hsinchu City (TW)

(21) Appl. No.: 18/163,889

(22) Filed: Feb. 3, 2023

(30) Foreign Application Priority Data
Dec. 26, 2022 (TW) 111149960

(51) Int. Cl. H01L 29/78; H01L 21/762

(52) U.S. Cl. CPC H01L 29/7846; H01L 21/76205

(57) ABSTRACT

A semiconductor device includes a substrate, a plurality of first epitaxial structures, a second epitaxial structure and a plurality of gate structures. The substrate includes a STI, a plurality of first recesses, a plurality of convex portions and a second recess adjacent to the STI. One of the convex portions is located between the second recess and the first recess that is closest to the STI, and each of the other convex portions is located between the two adjacent first recesses, in which the second recess is deeper than the first recesses. The first epitaxial structures are located in the first recesses of the substrate respectively. The second epitaxial structure is located in the second recess, in which a volume of the second epitaxial structure is greater than a volume of the first epitaxial structure. The gate structures are located on the convex portions of the substrate respectively.

### RELATED APPLICATIONS

This application claims priority to Taiwan Application Serial Number 111149960, filed Dec. 26, 2022, which is herein incorporated by reference.

### BACKGROUND

### Field of Disclosure

The present disclosure relates to a semiconductor device and a manufacturing method of the semiconductor device.

### Description of Related Art

Generally, in the manufacturing of transistors, shallow trench isolations (STI) will be formed on both sides of a series of transistors. Since the material of STI is oxide instead of silicon, the volume of the source/drain area closest to the STI will be smaller than the volume of other source/drain areas in epitaxial growth, which results in STI proximity effect, such that the channel strain along the [110] direction became smaller from the epitaxial structure.

Since the volume of the epitaxial structure became smaller, strain relaxation along the channel tends to occur to this epitaxial structure, such that the strain toward the channel adjacent to the epitaxial structure decreases, which results in the reduction of the channel mobility of charge carrier and the reduction of the saturation current, which affects the operation of the transistor.

### SUMMARY

One aspect of the present disclosure provides a semiconductor device.

According to one embodiment of the present disclosure, a semiconductor device includes a substrate, a plurality of first epitaxial structures, a second epitaxial structure and a plurality of gate structures. The substrate includes a shallow trench isolation (STI), a plurality of first recesses, a plurality of convex portions and a second recess adjacent to the STI. One of the convex portions is located between the second recess and the first recess that is closest to the STI, and each of the other convex portions is located between the two adjacent first recesses, in which the second recess is deeper than the first recesses. The first epitaxial structures are located in the first recesses of the substrate respectively. The second epitaxial structure is located in the second recess, in which a volume of the second epitaxial structure is greater than a volume of the first epitaxial structure. The gate structures are located on the convex portions of the substrate respectively.

In some embodiments of the present disclosure, a sidewall of each of the first recesses has a concave portion.

In some embodiments of the present disclosure, each of the first epitaxial structures has a convex portion, and the convex portion couples with the concave portion of the sidewall.

In some embodiments of the present disclosure, a sidewall of the second recess facing the STI has a concave portion.

In some embodiments of the present disclosure, the second epitaxial structure has a convex portion, and the convex portion couples with the concave portion of the sidewall of the second recess.

In some embodiments of the present disclosure, each of the first epitaxial structures includes a first epitaxial layer, a doped layer and a second epitaxial layer. The first epitaxial layer is located at a bottom portion of the first recesses. The doped layer is located on the first epitaxial layer. The second epitaxial layer is located on the doped layer.

In some embodiments of the present disclosure, the semiconductor device further includes a transition layer located between a bottom portion of the second recess and the second epitaxial structure.

In some embodiments of the present disclosure, the second epitaxial structure includes a first epitaxial layer, a doped layer and a second epitaxial layer. The first epitaxial layer is located on the transition layer. The doped layer is located on the first epitaxial layer. The second epitaxial layer is located on the doped layer.

In some embodiments of the present disclosure, a material of the first epitaxial layer includes silicon germanium, a material of the doped layer includes silicon germanium and boron, and a material of the second epitaxial layer includes silicon and without germanium.

In some embodiments of the present disclosure, a material of the transition layer includes germanium.

In some embodiments of the present disclosure, the second epitaxial structure has a top surface with an arc-shape.

In some embodiments of the present disclosure, the top surface of the second epitaxial structure extends from the STI to one of the gate structures.

One aspect of the present disclosure provides a manufacturing method of a semiconductor device.

According to one embodiment of the present disclosure, a manufacturing method of a semiconductor device includes forming a shallow trench isolation (STI) and a plurality of gate structures on a substrate; forming a plurality of first transition recesses between the gate structures on the substrate, and a second transition recess between the gate structure closest to the STI and the STI; implanting an ion to the second transition recess to form a transition layer; etching the first transition recesses and the second transition recess to form the first recesses and the second recess respectively, in which the second recess is deeper than the first recesses; and growing a plurality of first epitaxial structures and a second epitaxial structure in the first recesses and the second recess respectively, in which a volume of the second epitaxial structure is greater than a volume of the first epitaxial structure.

In some embodiments of the present disclosure, implanting the ion to the second transition recess to form the transition layer includes implanting germanium ion to the second transition recess.

In some embodiments of the present disclosure, forming the first transition recesses between the gate structures on the substrate, and the second transition recess between the gate structure closest to the STI and the STI such that a depth of the first transition recesses and the second transition recess are the same.

In some embodiments of the present disclosure, the manufacturing method of the semiconductor device further includes before implanting the ion to the second transition recess, coating a photoresist on the substrate such that the first transition recesses are covered by the photoresist and the second transition recess is not covered by the photoresist.

In some embodiments of the present disclosure, the manufacturing method of the semiconductor device further includes after implanting the ion to the second transition recess, removing the photoresist.

In some embodiments of the present disclosure, forming the first transition recesses and the second transition recess is performed by dry etching, and etching the first transition recesses and the second transition recess is performed by wet etching.

In some embodiments of the present disclosure, growing the first epitaxial structures and the second epitaxial structure in the first recesses and the second recess respectively includes growing a first epitaxial layer in the first recesses, in which a material of the first epitaxial layer includes silicon germanium; doping an ion to the first epitaxial layer to form a doped layer, in which a material of the doped layer includes silicon germanium and boron; and growing a second epitaxial layer on the doped layer, in which a material of the second epitaxial layer includes silicon and without germanium.

In some embodiments of the present disclosure, growing the first epitaxial structures and the second epitaxial structure in the first recesses and the second recess respectively includes growing a first epitaxial layer in the second recess, in which a material of the first epitaxial layer includes silicon germanium; doping an ion to the first epitaxial layer to form a doped layer, in which a material of the doped layer includes silicon germanium and boron; and growing a second epitaxial layer on the doped layer, in which a material of the second epitaxial layer includes silicon and without germanium.

In the aforementioned embodiments of the present disclosure, Since the step of ion implantation is performed, such that when etching the first transition recesses and the second transition recess, the second transition recess implanted with ion can form a deeper second recess than the first recesses in the same etching time, and thereby grows a second epitaxial structure whose volume is greater than the volume of the first epitaxial structure in the following step of epitaxial growth. So that the source/drain region closest to the STI (i.e. the second epitaxial structure) won't exert insufficient channel strain because of the insufficient volume of the epitaxial structure. Furthermore, since the second epitaxial structure is grown on the transition layer, such that the misfit dislocation defect is reduced and reduces the strain relaxation. By exerting enough compressive stress to the silicon channel can effectively improve the channel mobility of the charge carrier adjacent to the STI, which solves the STI proximity effect and sorts out the problem of the decrease of saturation current.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device according to one embodiment of the present disclosure.

FIG. 2 is an enlarged view of the first epitaxial structure of FIG. 1.

FIG. 3 is an enlarged view of the second epitaxial structure of FIG. 1.

FIG. 4 to FIG. 7 are cross-sectional views at intermediate steps of a manufacturing method of the semiconductor device of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the drawings. The spatially relative terms are intended to encompass different orientations of the device in use or operation in addition to the orientation depicted in the drawings. The apparatus may be otherwise oriented (rotated 90 degrees or at other orientations) and the spatially relative descriptors used herein may likewise be interpreted accordingly.

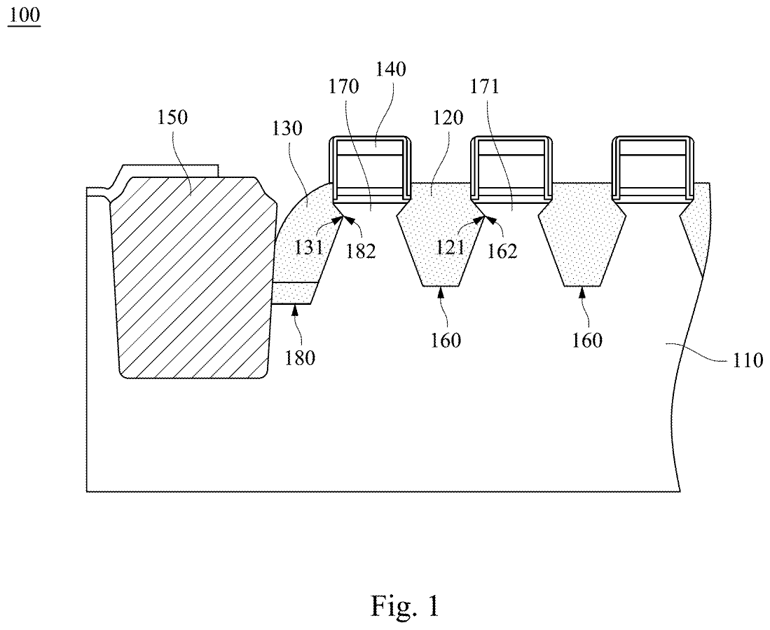

FIG. 1 is a cross-sectional view of a semiconductor device according to one embodiment of the present disclosure. Refer to FIG. 1, a semiconductor device 100 includes a substrate 110, a plurality of first epitaxial structures 120, a second epitaxial structure 130 and a plurality of gate structures 140. The material of the substrate 110 includes silicon, such as a silicon wafer. The substrate 110 includes a shallow trench isolation (STI) 150, a plurality of first recesses 160, a plurality of convex portions 170, 171 and a second recess 180 adjacent to the STI 150. One of the convex portions 170 is located between the second recess 180 and the first recess 160 that is closest to the STI 150, and each of the other convex portions 171 is located between the two adjacent first recesses 160, in which the second recess 180 is deeper than the first recesses 160. The first epitaxial structures 120 are located in the first recesses 160 of the substrate 110 respectively. The second epitaxial structure 130 is located in the second recess 180, in which a volume of the second epitaxial structure 130 is greater than a volume of the first epitaxial structure 120. The gate structures 140 are located on the convex portions 170, 171 of the substrate 110 respectively.

A sidewall of each of the first recesses 160 has a concave portion 162. Each of the first epitaxial structures 120 has a convex portion 121, and the convex portion 121 couples with the concave portion 162 of the sidewall. A sidewall of the second recess 180 facing the STI 150 has a concave portion 182. The second epitaxial structure 130 has a convex portion 131, and the convex portion 131 couples with the concave portion 182 of the sidewall of the second recess 180. As a result of such a design, the first epitaxial structures 120 can exert a strain to the convex portions 170, such that the channel mobility of the charge carrier increases, which enables the increase of saturation current of the semiconductor device 100 when operating.

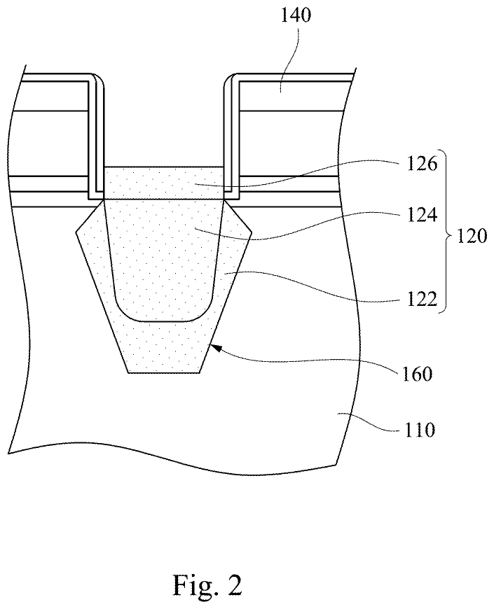

FIG. 2 is an enlarged view of the first epitaxial structure 120 of FIG. 1. Refer to FIG. 2, each of the first epitaxial structures 120 includes a first epitaxial layer 122, a doped layer 124 and a second epitaxial layer 126. The first epitaxial layer 122 is located at the bottom portion of the first recess 160. The doped layer 124 is located on the first epitaxial layer 122. The second epitaxial layer 126 is located on the doped layer 124. The material of the first epitaxial layer 122 includes silicon germanium (SiGe), the material of the doped layer 124 includes silicon germanium (SiGe) and boron (B), and the material of the second epitaxial layer 126 includes silicon and without germanium, but the materials of the first epitaxial structures 120 are not limited to these.

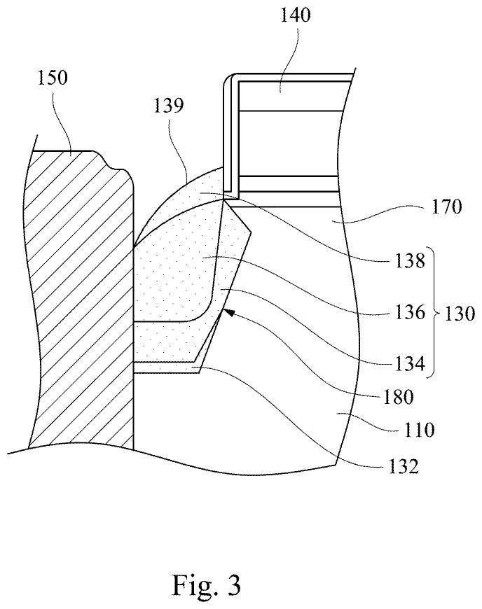

FIG. 3 is an enlarged view of the second epitaxial structure of FIG. 1. Refer to FIG. 3, the semiconductor device 100 further includes a transition layer 132 located between the bottom portion of the second recess 180 and the second epitaxial structure 130. The second epitaxial structure 130 includes a first epitaxial layer 134, a doped layer 136 and a second epitaxial layer 138. The first epitaxial layer 134 is located on the transition layer 132. The doped layer 136 is located on the first epitaxial layer 134. The second epitaxial layer 138 is located on the doped layer 136. The second epitaxial structure 130 includes the same materials as the first epitaxial structures 120. For example, the material of the first epitaxial layer 134 includes silicon germanium (SiGe), the material of the doped layer 136 includes silicon germanium (SiGe) and boron (B), and the material of the second epitaxial layer 138 includes silicon and without germanium. Furthermore, since a side of the second epitaxial structure 130 is adjacent to the STI 150, the structure after epitaxial growth includes a top surface 139 with an arc-shape, and the top surface 139 of the second epitaxial structure 130 extends from the STI 150 to one of the gate structures 140.

Since the volume of the second epitaxial structure 130 located in the second recess 180 is greater than the volume of the first epitaxial structure 120 located in the first recess 160, such that the source/drain region closest to the STI 150 can exert sufficient compressive stress to the channel in the convex portion 170 adjacent to it. Furthermore, since the second epitaxial structure is grown on the transition layer, such that the misfit dislocation defect is reduced and reduces the strain relaxation. By exerting enough compressive stress to the silicon channel can effectively improve the channel mobility of the charge carrier adjacent to the STI, which solves the STI proximity effect and sorts out the problem of the decrease of saturation current.

It is to be noted that the connection relationships, the materials, and the advantages of the elements described above will not be repeated in the following description. In the following description, a manufacturing method of the semiconductor device is described.

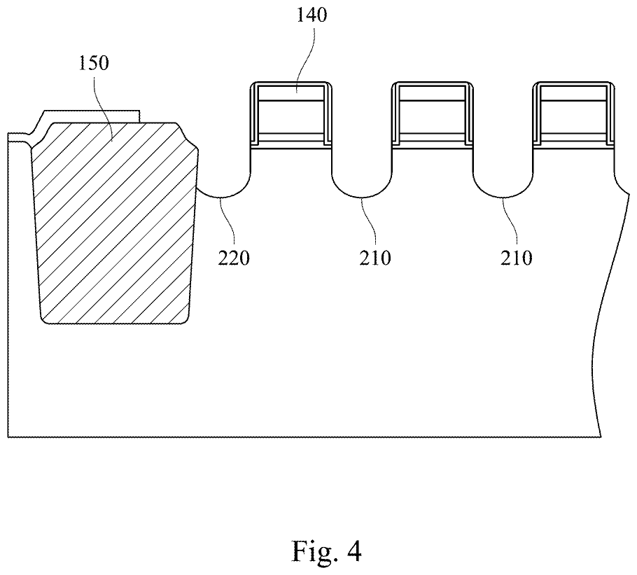

FIG. 4 to FIG. 7 are cross-sectional views at intermediate steps of a manufacturing method of a semiconductor device of FIG. 1. Refer to FIG. 4, a manufacturing method of a semiconductor device includes forming a shallow trench isolation (STI) 150 and a plurality of gate structures 140 on the substrate 110. Thereafter, forming a plurality of first transition recesses 210 between the gate structures 140 on the substrate 110, and a second transition recess 220 between the gate structure 140 closest to the STI 150 and the STI 150. At this step, the depth of the first transition recesses 210 and the depth of the second transition recess 220 are the same. In the present embodiment, forming the first transition recesses 210 and the second transition recess 220 is performed by dry etching. The plasma free radical used for dry etching includes hydrobromic acid (HBr), chlorine (Cl₂) and hydrogen gas (H₂), but not limited to these.

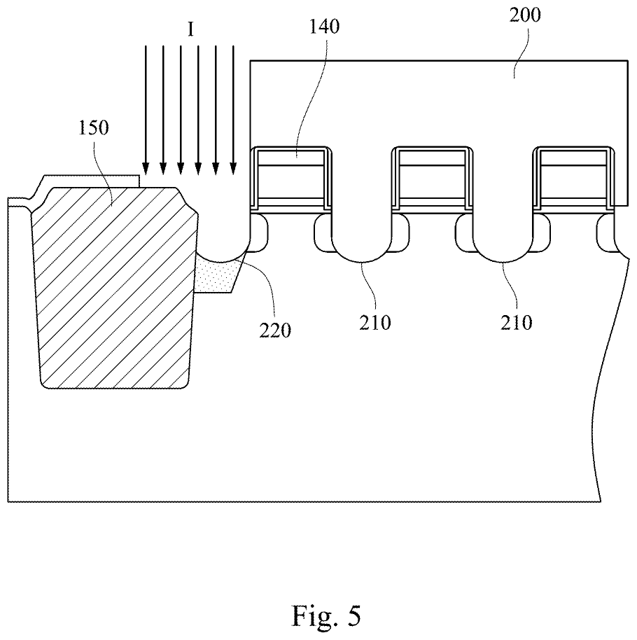

Refer to FIG. 5, after the first transition recesses 210 and the second transition recess 220 is formed and before implanting the ion to the second transition recess 220, coating a photoresist 200 on the substrate 110 such that the first transition recesses 210 are covered by the photoresist 200 and the second transition recess 220 is not covered by the photoresist 200. This step can ensure that in the next step which is an ion implantation, only the second transition recess 220 will be implanted with an ion I. Thereafter, implanting the ion I to the second transition recess 220 to form a transition layer 132. In the present embodiment, implanting the ion I to the second transition recess 220 to form the transition layer 132 includes implanting germanium ion to the second transition recess 220.

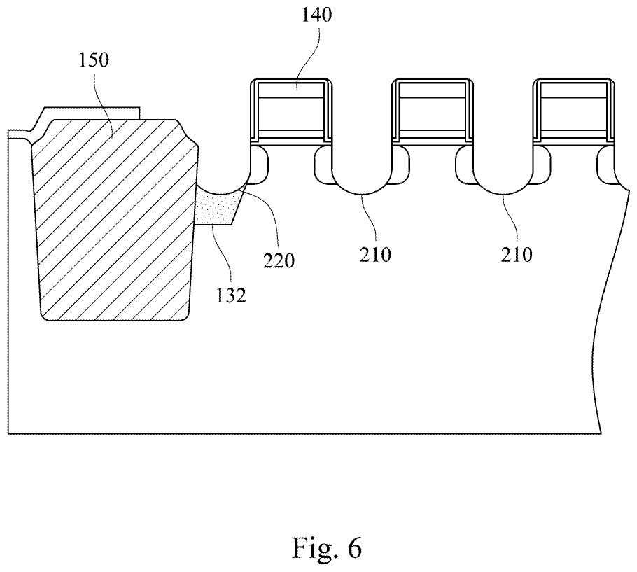

Refer to FIG. 6, after implanting the ion I to the second transition recess 220, removing the photoresist 200. At this time, the depth of the first transition recesses 210 and the depth of the second transition recess 220 has not changed very much. However, since the second transition recess 220 is implanted with the ion I and forms a transition layer 132, the etching rate of the next etching step will be different.

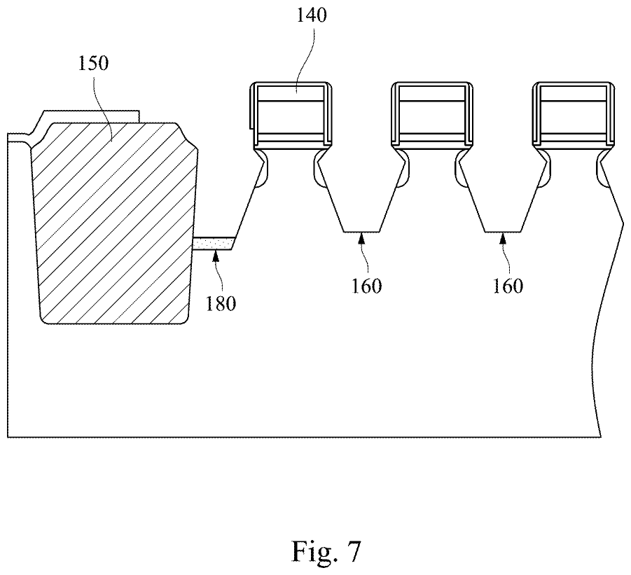

Refer to FIG. 7, thereafter, etching the first transition recesses 210 and the second transition recess 220 to form the first recesses 160 and the second recess 180 respectively, in which the second recess 180 is deeper than the first recesses 160. Since the second transition recess 220 has been implanted with the ion I, the etching rate of the second transition recess 220 will be faster in the etching process, and thus forming the second recess 180 that is deeper than the first recesses 160. Etching the first transition recesses 210 and the second transition recess 220 is performed by wet etching.

Refer to FIG. 7 and FIG. 1, thereafter, growing a plurality of first epitaxial structures 120 and a second epitaxial structure 130 in the first recesses 160 and the second recess 180 respectively, in which the volume of the second epitaxial structure 130 is greater than the volume of the first epitaxial structure 120.

In particular, refer to FIG. 1 and FIG. 2, growing the first epitaxial structures 120 and the second epitaxial structure 130 in the first recesses 160 and the second recess 180 respectively includes growing a first epitaxial layer 122 in the first recesses 160, in which the material of the first epitaxial layer includes silicon germanium; doping an ion to the first epitaxial layer 122 to form a doped layer 124, in which the material of the doped layer includes silicon germanium and boron; and growing a second epitaxial layer 126 on the doped layer 124, in which the material of the second epitaxial layer 126 includes silicon and without germanium.

Refer to FIG. 1 and FIG. 3, growing the first epitaxial structures 120 and the second epitaxial structure 130 in the first recesses 160 and the second recess 180 respectively includes growing a first epitaxial layer 134 in the second recess 180, in which the material of the first epitaxial layer 134 includes silicon germanium; doping an ion to the first epitaxial layer to form a doped layer 136, in which the material of the doped layer 136 includes silicon germanium and boron; and growing a second epitaxial layer 138 on the doped layer 136, in which the material of the second epitaxial layer 138 includes silicon and without germanium.

Since the step of ion implantation is performed, such that when wet etching, the silicon-contained substrate 110 can form a deeper second recess 180 than the first recesses 160 in the same etching time, and thereby grows an second epitaxial structure 130 whose volume is greater than the volume of the first epitaxial structure 120 in the following step of epitaxial growth. So that the source/drain region closest to the STI 150 (i.e. the second epitaxial structure 130) won't exert insufficient channel strain because of the insufficient volume of the epitaxial structure. Furthermore, since the second epitaxial structure 130 is grown on the transition layer 132, such that the misfit dislocation defect is reduced and reduces the strain relaxation. By exerting enough compressive stress to the silicon channel can effectively improve the channel mobility of the charge carrier adjacent to the STI 150, which solves the STI proximity effect and sorts out the problem of the decrease of saturation current.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprises a shallow trench isolation (STI), a plurality of first recesses, a plurality of convex portions and a second recess adjacent to the STI, one of the convex portions is located between the second recess and the first recess that is closest to the STI, and each of the other convex portions is located between the two adjacent first recesses, wherein the second recess is deeper than the first recesses;
a plurality of first epitaxial structures located in the first recesses of the substrate respectively;
a second epitaxial structure located in the second recess, wherein a volume of the second epitaxial structure is greater than a volume of the first epitaxial structure; and
a plurality of gate structures located on the convex portions of the substrate respectively.

2. The semiconductor device of claim 1, wherein a sidewall of each of the first recesses has a concave portion.

3. The semiconductor device of claim 2, wherein each of the first epitaxial structures has a convex portion, and the convex portion couples with the concave portion of the sidewall.

4. The semiconductor device of claim 1, wherein a sidewall of the second recess facing the STI has a concave portion.

5. The semiconductor device of claim 4, wherein the second epitaxial structure has a convex portion, and the convex portion couples with the concave portion of the sidewall of the second recess.

6. The semiconductor device of claim 1, wherein each of the first epitaxial structures comprises:
a first epitaxial layer located at a bottom portion of the first recesses;
a doped layer located on the first epitaxial layer; and
a second epitaxial layer located on the doped layer.

7. The semiconductor device of claim 1, further comprising:
a transition layer located between a bottom portion of the second recess and the second epitaxial structure.

8. The semiconductor device of claim 7, wherein the second epitaxial structure comprises:
a first epitaxial layer located on the transition layer;
a doped layer located on the first epitaxial layer; and
a second epitaxial layer located on the doped layer.

9. The semiconductor device of claim 8, wherein a material of the first epitaxial layer comprises silicon germanium, a material of the doped layer comprises silicon germanium and boron, and a material of the second epitaxial layer comprises silicon and without germanium.

10. The semiconductor device of claim 7, wherein a material of the transition layer comprises germanium.

11. The semiconductor device of claim 1, wherein the second epitaxial structure has a top surface with an arc-shape.

12. The semiconductor device of claim 11, wherein the top surface of the second epitaxial structure extends from the STI to one of the gate structures.

13. A manufacturing method of a semiconductor device, comprising:
forming a shallow trench isolation (STI) and a plurality of gate structures on a substrate;
forming a plurality of first transition recesses between the gate structures on the substrate, and a second transition recess between the gate structure closest to the STI and the STI;
implanting an ion to the second transition recess to form a transition layer;
etching the first transition recesses and the second transition recess to form a plurality of first recesses and a second recess respectively, wherein the second recess is deeper than the first recesses; and
growing a plurality of first epitaxial structures and a second epitaxial structure in the first recesses and the second recess respectively, wherein a volume of the second epitaxial structure is greater than a volume of the first epitaxial structure.

14. The manufacturing method of the semiconductor device of claim 13, wherein implanting the ion to the second transition recess to form the transition layer comprises implanting germanium ion to the second transition recess.

15. The manufacturing method of the semiconductor device of claim 13, wherein forming the first transition recesses between the gate structures on the substrate, and the second transition recess between the gate structure closest to the STI and the STI such that a depth of the first transition recesses and a depth of the second transition recess are the same.

16. The manufacturing method of the semiconductor device of claim 13, further comprising:
before implanting the ion to the second transition recess, coating a photoresist on the substrate such that the first transition recesses are covered by the photoresist and the second transition recess is not covered by the photoresist.

17. The manufacturing method of the semiconductor device of claim 16, further comprising:
after implanting the ion to the second transition recess, removing the photoresist.

18. The manufacturing method of the semiconductor device of claim 13, wherein forming the first transition recesses and the second transition recess is performed by dry etching, and etching the first transition recesses and the second transition recess is performed by wet etching.

19. The manufacturing method of the semiconductor device of claim 13, wherein growing the first epitaxial structures and the second epitaxial structure in the first recesses and the second recess respectively comprising:
growing a first epitaxial layer in the first recesses, wherein a material of the first epitaxial layer comprises silicon germanium;
doping an ion to the first epitaxial layer to form a doped layer, wherein a material of the doped layer comprises silicon germanium and boron; and
growing a second epitaxial layer on the doped layer, wherein a material of the second epitaxial layer comprises silicon and without germanium.

20. The manufacturing method of the semiconductor device of claim 13, wherein growing the first epitaxial structures and the second epitaxial structure in the first recesses and the second recess respectively comprising:
growing a first epitaxial layer in the second recess, wherein a material of the first epitaxial layer comprises silicon germanium;
doping an ion to the first epitaxial layer to form a doped layer, wherein a material of the doped layer comprises silicon germanium and boron; and
growing a second epitaxial layer on the doped layer, wherein a material of the second epitaxial layer comprises silicon and without germanium.
